(19) United States
(12) Patent Application Publication
(10) Pub. No.: US 2009/0129036 A1
(43) Pub. Date: May 21, 2009

(54) SEMICONDUCTOR DEVICE AND ELECTRONIC DEVICE

(75) Inventors: SEIYA FUJII, Tokyo (JP); Fumitomo Watanabe, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/269,951

(22) Filed: Nov. 13, 2008

(30) Foreign Application Priority Data
Nov. 21, 2007 (JP) 2007-301922

(51) Int. Cl. H01L 23/538; H05K 7/02

(52) U.S. Cl. 361/760; 257/698; 257/E23.169

(57) ABSTRACT

A semiconductor device includes: a wiring substrate that includes multiple connection pads provided on a top surface thereof and multiple lands provided on a bottom surface thereof and electrically connected to the connection pads, respectively; a semiconductor chip that is mounted on the top surface of the wiring substrate; multiple electrode pads provided on the semiconductor chip; wirings that electrically connect the electrode pads and the connection pads, respectively; a seal that is made of an insulating resin and covers at least the semiconductor chip and the wirings; and a through hole that is provided on a peripheral region of the wiring substrate, into which a fixing member is to be attached by insertion

### BACKGROUND OF THE INVENTION

1. Field of the Invention

The present invention relates to a semiconductor device formed by a semiconductor chip being mounted on a package substrate, and to an electronic device including the semiconductor device.

Priority is claimed on Japanese Patent Application No. 2007-301922, filed Nov. 21, 2007, the content of which is incorporated herein by reference.

2. Description of the Related Art

Recently, greater miniaturization and multi-layering of wirings have been progressing with the further integration of semiconductor chips. On the other hand, miniaturization of the package size is required for high-density packaging of a semiconductor package (semiconductor device). For example, a semiconductor package, such as BGA (ball grid array) and CSP (chip size package), has a structure in which a semiconductor chip is mounted on a package substrate, and the semiconductor chip and the package substrate are connected using wire bonding, for example. In this case, solder balls for external connection can be arranged at the rear surface of the package substrate. Thereby, the semiconductor package is applicable to multiple pins.

A conventional BGA-type semiconductor device mainly includes a wiring substrate having multiple connection pads provided on the top surface thereof and multiple lands provided on the bottom surface thereof and electrically connected to the connection pads, a semiconductor chip mounted on the top surface of the wiring substrate, wirings to electrically connect electrode pads provided on the semiconductor chip and the connection pads, a seal made of an insulating resin and covering the semiconductor chip and the wirings, and external terminals provided on the lands.

The conventional BGA-type semiconductor device is mounted on compact electronic devices, such as a cellular phone, and therefore required to withstand stress due to a difference in thermal expansion coefficients between the wiring substrate and the semiconductor chip, or mechanical impact, such as when an electronic device is dropped.

For this reason, techniques are provided in which the sizes of external terminals (bumps) at four corners of the wiring substrate among multiple bumps mounted on the wiring substrate in a grid pattern are set to be larger than other bumps to reinforce the bumps at the four corners on which stress focuses, and thereby to increase the reliability of second mounting of the semiconductor device. Such techniques are disclosed in, for example, Japanese Unexamined Patent Applications, First Publication Nos. 2001-210749 and 2006-294656.

Additionally, a technique of providing through holes for releasing heat on a wiring substrate of a semiconductor device is disclosed in Japanese Unexamined Patent Application, First Publication No. 2007-96035.

However, in the techniques of setting the bumps at four corners to be larger than the other bumps, the height of the bumps might become higher when solder balls are mounted thereon, although the reliability of second mounting can be enhanced to some extent by reinforcing the bumps at the four corners on which stress focuses. As a result, the height of the bumps to be mounted on the wiring substrate varies. Therefore, the mounting quality might deteriorate due to the variation in the height of the bumps. Additionally, the reliability of second mounting for mechanical impact caused by, for example, electronic devices is not considered.

Further, in the technique of providing the through holes for releasing heat, the through holes need to be formed in consideration of wiring regions, or wirings need to be arranged avoiding the through holes since the through holes are provided on the inside of the outermost bumps, resulting in a complex wiring layout design. Additionally, the pitch of bumps has been narrowing with the increasing number of terminals due to, for example, the higher-performance semiconductors, or with the miniaturization of semiconductor devices, resulting in difficulty in providing through holes avoiding wirings.

Moreover, the reliability of second mounting, such as thermal stress, mechanical impact, or joint strength between the bumps of the semiconductor device and a mounting substrate, is not considered. Additionally, the through holes are provided in the vicinity of a semiconductor chip. Therefore, moisture might invade from the boundary surface between the wiring substrate and the resin which are inside the through hole, thereby affecting the semiconductor chip.

### SUMMARY OF THE INVENTION

A semiconductor device according to one aspect of the present invention may include: a wiring substrate that includes multiple connection pads on a top surface thereof and multiple lands provided on a bottom surface thereof and electrically connected to the connection pads, respectively; a semiconductor chip mounted on the top surface of the wiring substrate; multiple electrode pads provided on the semiconductor chip; wirings that electrically connect the electrode pads and the connection pads, respectively; a seal that is made of an insulating resin and covers at least the semiconductor chip and the wirings; and a through hole that is provided on a peripheral region of the wiring substrate, into which a fixing member is to be attached by insertion.

An electronic device according to another aspect of the present invention may include the semiconductor device according to claim 1, and a mounting substrate on which multiple electronic parts including the semiconductor device are mounted. The fixing member fixes the semiconductor device onto the mounting substrate.

According to the semiconductor device and the electronic device, through holes into which the fixing member is attached by insertion are provided on a peripheral region of the semiconductor device. As a result, the semiconductor device can reinforcingly be connected to the mounting substrate by the fixing member being attached by insertion into the through hole without interfering with wirings on the wiring substrate, thereby enhancing the reliability of second mounting. Additionally, the through holes can be used for a position setting upon a mounting, thereby enhancing mounting accuracy. Further, no reflow is required, and therefore mounting of electronic parts can be simplified, and the electronic parts can easily be exchanged when an adhesive is not used.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plane view showing a bottom surface (on which external terminals are formed) of a semiconductor device according to a first embodiment of the present invention;

FIG. 1B is a cross-sectional view taken along an A-A′ line shown in FIG. 1A;

FIG. 2 is a plane view showing an application of through holes of the semiconductor device;

FIG. 3 is a plane view showing another application of through holes of the semiconductor device;

FIG. 4 is a cross-sectional view showing a mounting structure of the semiconductor device;

FIG. 5 is a plane view showing a wiring motherboard used for the semiconductor device;

FIG. 6 is a process chart showing a method of manufacturing the semiconductor device;

FIG. 7 is a cross-sectional view showing a mounting structure of the semiconductor device;

FIG. 8 is a cross-sectional view showing a mounting structure of the semiconductor device;

FIG. 9 is a cross-sectional view showing a mounting structure of the semiconductor device;

FIG. 10 is a cross-sectional view showing a mounting structure of the semiconductor device; and

FIG. 11 is a cross-sectional view showing an electronic device according to the first embodiment of the present invention.

### DETAILED DESCRIPTION OF THE INVENTION

The invention will now be described herein with reference to illustrative embodiments. The accompanying drawings explain a semiconductor device and an electronic device in the embodiments, and the size, the thickness, and the like of each illustrated portion might be different from those of each portion of an actual semiconductor device and an actual electronic device.

Those skilled in the art will recognize that many alternative embodiments can be accomplished using the teachings of the present invention and that the invention is not limited to the embodiments illustrated herein for explanatory purpose.

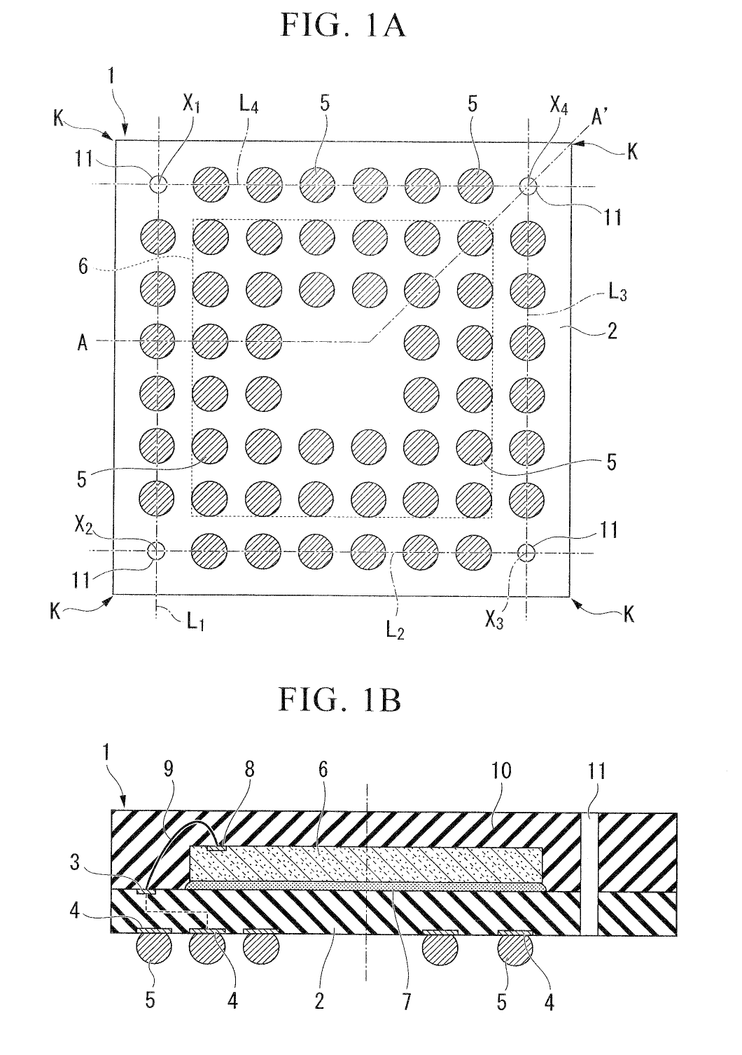

Hereinafter, a semiconductor device 1 according to a first embodiment of the present invention is explained. As shown in FIG. 1, the semiconductor device 1 mainly includes a wiring substrate 2 that is in substantially a rectangular shape when planarly viewed and includes multiple connection pads 3 on the top surface thereof and multiple lands 4 on the bottom surface thereof and electrically connected to the connection pads 3, a semiconductor chip 6 mounted on the top surface of the wiring substrate 2, electrode pads 8 provided on the semiconductor chip 6, wirings 9 that electrically connect the electrode pads 8 and the connection pads 3, a seal 10 made of an insulating resin and covering the semiconductor chip 6 and the wirings 9, external terminals 5 provided on the lands 4, and a through hole 11 into which a fixing member is to be attached by insertion.

Wirings are provided on the wiring substrate 2. The semiconductor chip 6 is fixed on substantially the center of the top surface of the wiring substrate 2 by an insulating adhesive 7, and the lands 4 electrically connected to the connection pads 3 are provided on the bottom surface thereof. Solder balls to be the external terminals 5 are installed in the lands 4. The external terminals 5 are arranged in a grid pattern at a given pitch.

Preferably, the wiring substrate 2 is in substantially a quadrangular shape as shown in FIG. 1A. The wiring substrate 2 may be, for example, 10 mm×10 mm using a glass epoxy substrate of 0.25 mm. The seal 10 covering the semiconductor chip 6 and the wirings 9 is provided on the top surface of the wiring substrate 2. The seal 10 is made of, for example, a thermosetting resin, such as an epoxy resin.

For example, a logic circuit or a memory circuit is provided on a surface of the semiconductor chip 6, and the electrode pads 8 are provided on the outer circumference of the surface. The electrode pads 8 are electrically connected to the corresponding connection pads 3 through the conductive wirings 9. The wirings 9 may be made of, for example, Au or Cu.

The through holes 11 in lieu of the external terminals 5 are provided at the four corners K of the wiring substrate 2. In other words, the through holes 11 are provided at the intersections X₁ to X₄ of arrangement lines L₁ to L₄ along which the outermost external terminals 5 are arranged. As shown in FIG. 1B, the through hole 11 penetrates from the bottom surface of the wiring substrate 2 to the top surface of the seal 10. Wirings are prohibited from being arranged at the positions of the through holes as wiring prohibition regions.

Preferably, the through hole 11 is 100 to 500 μm in diameter which is substantially the same as a ball diameter of the bump so that the through hole 11 is arranged at a corner of the bumps (external terminals 5), for example. However, the through hole 11 may be greater than 500 μm since a larger through hole 11 is more effective.

The through holes 11 may be provided on a peripheral region of the wiring substrate 2. Preferably, the through holes 11 are provided at least at two opposing corners K. More preferably, the through holes 11 are provided at every corner K.

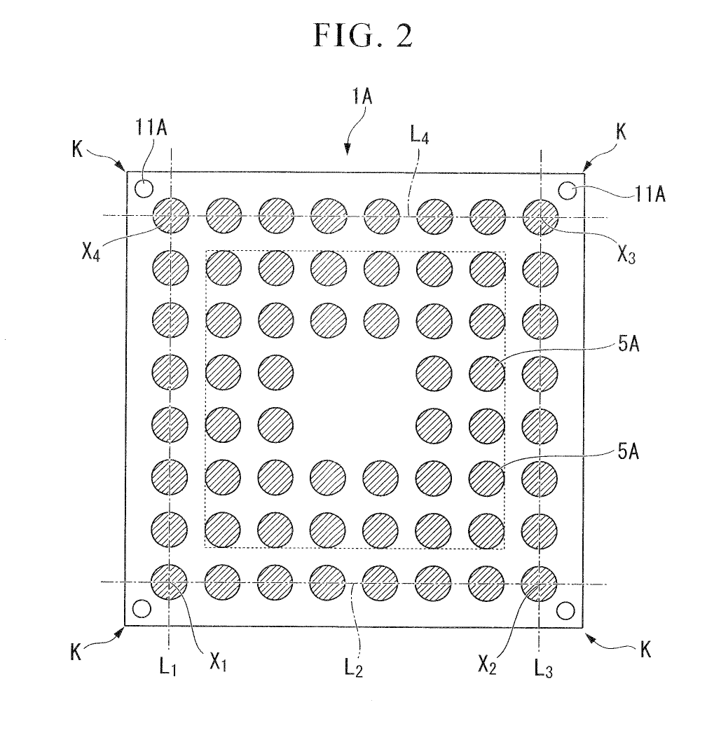

For example, as shown in FIG. 2, the through holes 11A may be arranged at the corners of the wiring substrate 2A of the semiconductor device 1A and outside the intersections XI to X4 of the arrangement lines L1 to L4 along which the outermost external terminals 5A are arranged. In this manner, the through holes 11A can be formed without affecting the number of wirings and external terminals 5A on the wiring substrate 2A.

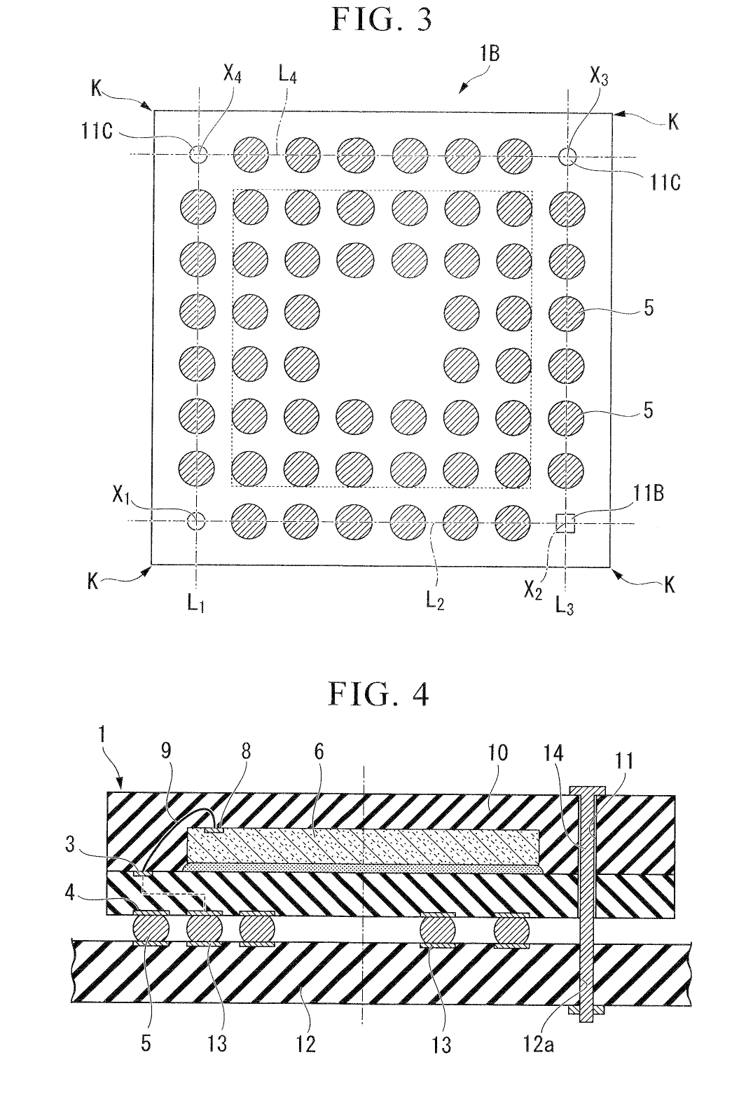

As shown in FIG. 3, one through hole 11B may have a different shape from those of other through holes 11C, and thereby can be used as an index of the semiconductor device 1B.

Hereinafter, a mounting structure of the semiconductor device 1 is explained. As shown in FIG. 4, the external terminals 5 are mounted on lands 13 on a mounting substrate 12, and a fixing member 14, such as a bolt, a nut, or a screw, is inserted into the through holes 11 formed on the four corners of the semiconductor device 1 to reinforce the connection between the semiconductor device 1 and the mounting substrate 12.

Thus, the through holes 11 are provided on the peripheral region of the BGA-type semiconductor device 1. Thereby, an electronic device can be reinforcingly connected to the mounting substrate 12. Particularly, the reinforcing connection is implemented by using the through holes 11 at the four corners instead of external terminals 5 arranged at the four corners where stress to the semiconductor device 1 is likely to occur, thereby enhancing the reliability of second mounting. Additionally, the through holes 11 may be used for a position setting when the semiconductor device 1 is mounted on the mounting substrate 12.

Further, the reliability of second mounting of the semiconductor device 1 on the mounting substrate 12 is enhanced, thereby enhancing the reliability of the electronic device including the mounting substrate 12.

Hereinafter, a method of manufacturing the semiconductor device 1 according to the first embodiment is explained.

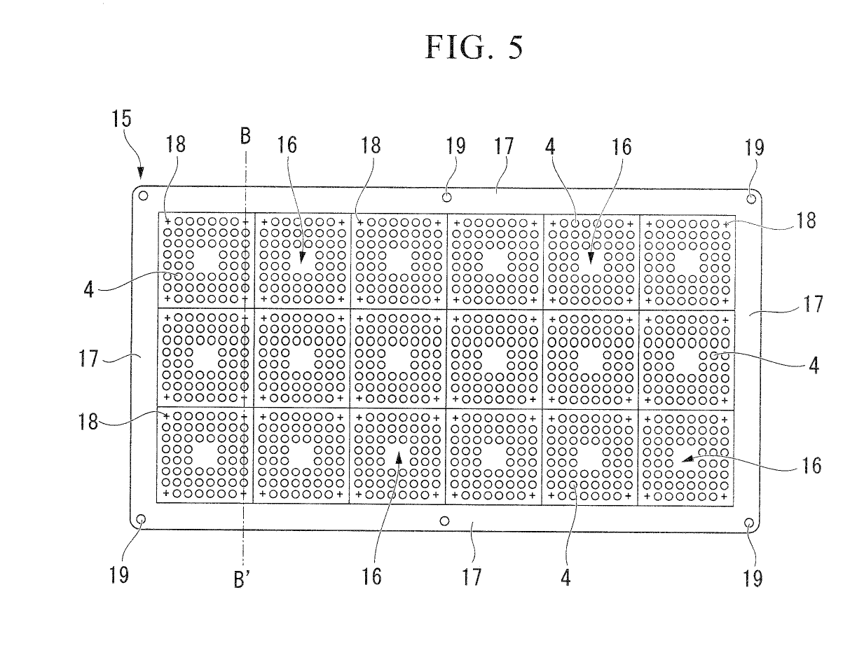

As shown in FIG. 5, a wiring motherboard 15 to be used for the semiconductor device 1 is processed by MAP (mold array process) and includes multiple product forming sections 16 and a frame section 17.

The product forming sections 16 are sections to be cut and separated into multiple pieces, and each piece becomes the aforementioned wiring substrate 2 and has the same structure as that of the wiring substrate 2. Marks 18 for forming the through holes 11 are arranged in a matrix on the four corners of each product forming section 16.

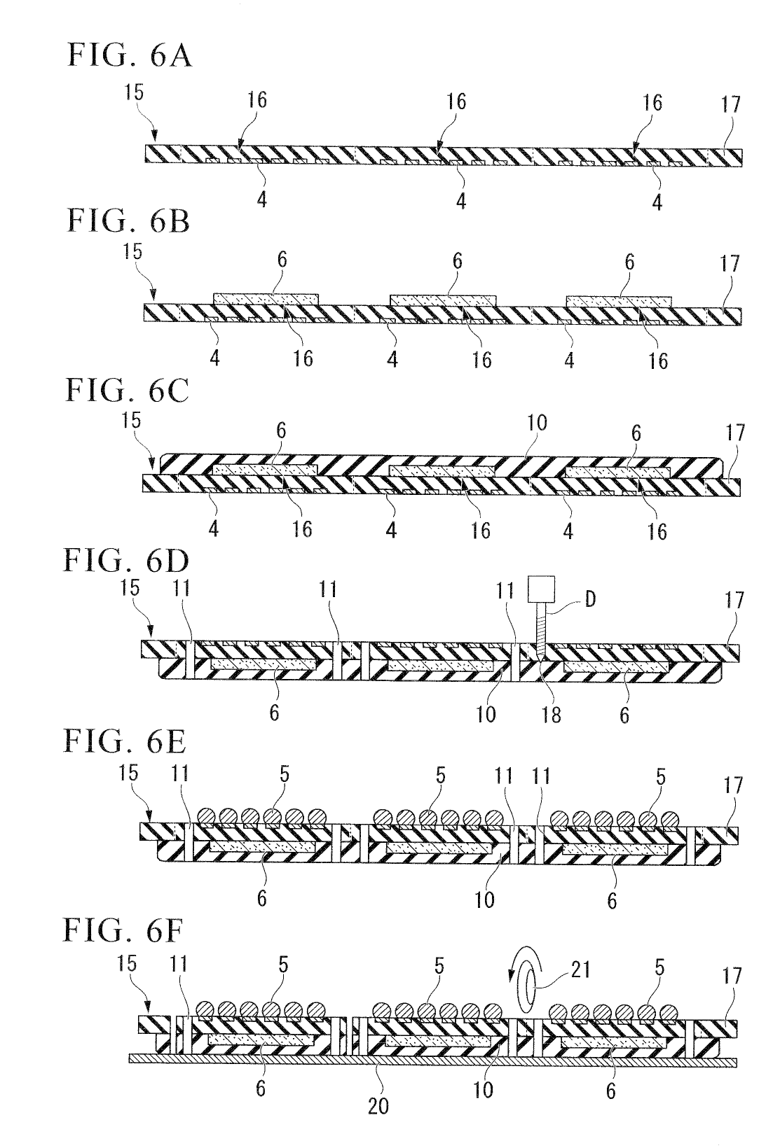

The frame section 17 is provided surrounding the product forming sections 16 arranged in a matrix. Position setting holes 19 are provided at a given interval on the frame section 17 for transportation and position setting. Boundaries among the product forming sections 16 are dicing lines. In this manner, the wiring motherboard 15 shown in FIGS. 5 and 6 is prepared.

Then, the semiconductor chip 6 is fixed on the top surface of each product forming section 16 of the wiring motherboard 15 by the insulating adhesive 7 as shown in FIG. 6B. The electrode pads 8 on the top surface of the semiconductor chip 6 are connected to the connection pads 3 on the product forming section 16 using the conductive wirings 9.

The wiring 9 is made of, for example, Au. The wiring 9 which is melted to form a ball at one end thereof is connected to the electrode pad 8 on the semiconductor chip 6 by ultrasonic thermocompression bonding using a non-depicted wire bonding apparatus. Then, the wiring 9 is made in a given loop shape, and the other end of the wiring 9 is connected to the connection pad 3 by ultrasonic thermocompression bonding.

Then, the seal 10 that is made of an insulating resin and covers all of the product forming sections 16 on the wiring motherboard 15 is formed as shown in FIG. 6C. The seal 10 is formed by, for example, clamping the wiring motherboard 15 using upper and lower molds of a transfer molding apparatus, injecting a thermosetting epoxy resin from a gate into a cavity formed by the upper and lower molds, and thermal-curing the epoxy resin filled in the cavity.

Then, the through holes 11 are formed at the positions of the marks 18 provided on the product forming sections 16 on the wiring motherboard 15 using a boring member D, such as a drill, as shown in FIG. 6D. The through holes 11 are formed penetrating from the bottom surface of the wiring substrate 2 to the top surface of the seal 10. The through holes 11 may be formed using, for example, a laser. The through hole 11 may not be formed at a defective product forming section so that a defective product can be easily identified.

Then, conductive balls are mounted on the multiple lands 4 arranged in a grid pattern on the bottom surface of the wiring motherboard 15 to form the external terminals as shown in FIG. 6E. In the ball mounting process, a non-depicted suction mechanism is used in which multiple suction holes are provided at positions corresponding to those of the lands on the wiring motherboard 15. Balls made of, for example, solder are held on the suction holes, flux is applied to the held balls, and then the balls are mounted on the lands 4 of the wiring motherboard 15. After the balls are mounted, reflow is performed to form the external terminals 5.

The wiring motherboard 15 is cut along the dicing lines, and the product forming sections 16 are separated as shown in FIG. 6F. In the board dicing process, the seal 10 of the wiring motherboard 15 is bonded on a dicing tape 20 to sustain the wiring motherboard 15. The wiring motherboard 15 is cut into pieces along the dicing lines using a dicing blade 21 rotating at high speed. Then, each piece is picked up from the dicing tape to acquire the semiconductor device 1 shown in FIG. 1.

Hereinafter, an electronic device according to the first embodiment is explained. The electronic device according to the first embodiment includes the semiconductor device 1 and the mounting substrate 12 on which multiple electronic parts including the semiconductor device 1 are mounted. The fixing member 14 is provided for fixing the semiconductor device 1 to the mounting substrate 12.

The type of the fixing member 14 can be selected according to the reliability required for the semiconductor device 1. If TC (Temperature Cycle) resistance is required, for example, the fixing member 14 is preferably made of not a metal, but an elastic member, such as a spring or rubber, so that warpage of the semiconductor device due to a difference in thermal expansion coefficients is absorbed by the elastic member being stretched. In this case, enhancement of the reliability of second mounting can be expected compared to a case of a fixing by a metal member in which stress due to the difference in thermal expansion coefficients cannot be released.

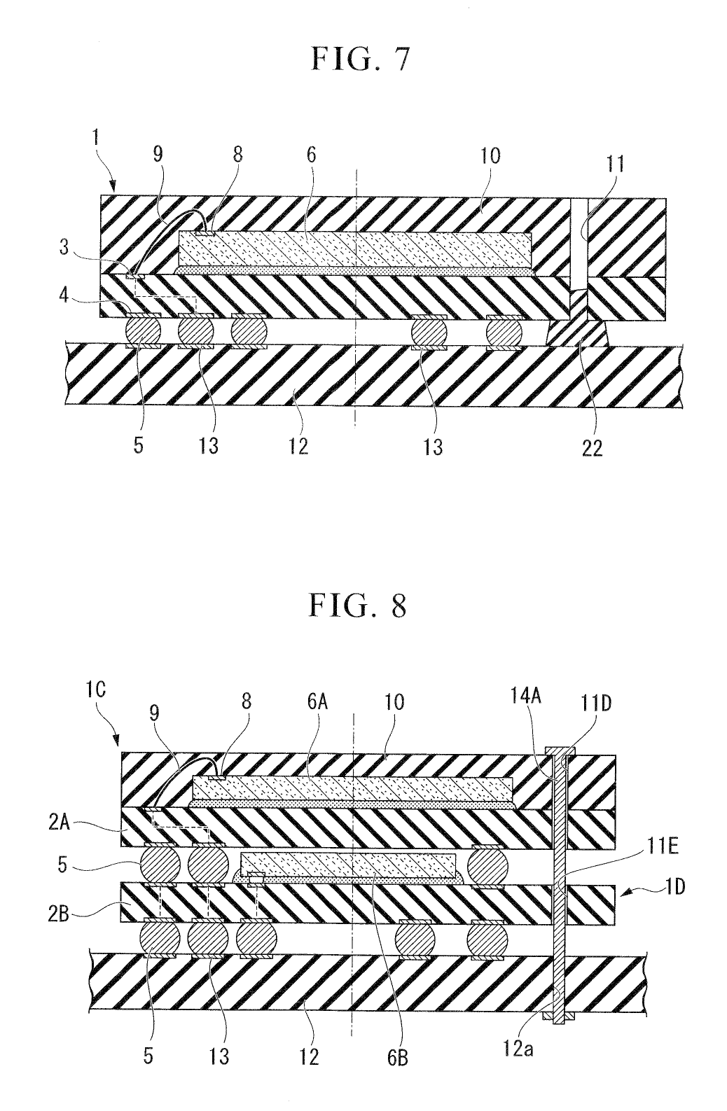

If an elastic member 22 made of an elastic material, such as rubber, is used, the elastic member 22 is bonded on the mounting substrate 12 as shown in FIG. 7. Thereby, the bonded area can increase, and the semiconductor device 1 can be reliably mounted. Since the through hole 11 is provided, the elastic member 22 can be formed by injecting an elastic material from the through hole 11 after the semiconductor device 1 is mounted on the mounting substrate 12.

Due to the reinforcing connection, enhancement of TC resistance as well as impact resistance can be expected. Since the elastic member 22, such as rubber, is used, warpage of the semiconductor device due to the difference in thermal expansion coefficients is absorbed by the elastic member being stretched. Since the elastic member 22 is arranged at a corner of the external terminals 5, stress focused on the corner at the time of a TC test is received by the elastic member 22 in lieu of the external terminal 5, achieving a dummy dump effect. Due to these effects, the reliability of the second mounting of the semiconductor device 1 can be enhanced.

Since the insulating elastic member 22 is used as an adhesive for the second mounting, the external terminals do not short out even if the elastic member 22 is spread on the mounting board 12.

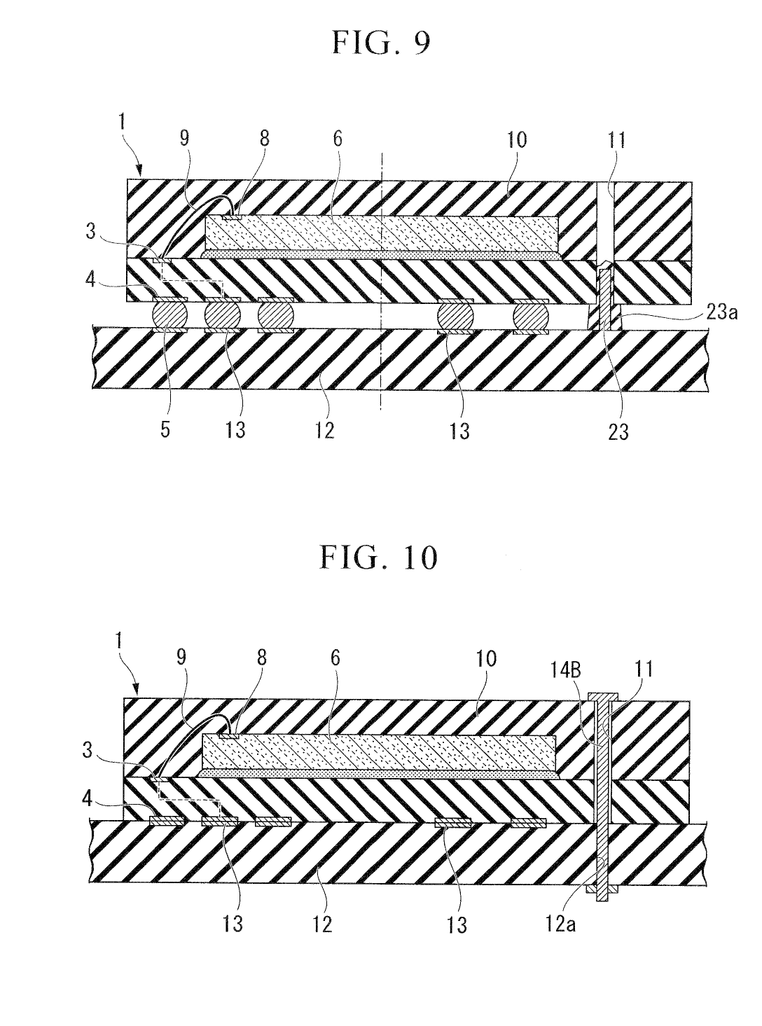

Additionally, the fixing member 14 may be a metal member made of a metal material, and the metal member is preferably bonded on the semiconductor device 1 and the mounting substrate 12 using, for example, an adhesive. Since the metal member is integrated with the semiconductor device 1 and the mounting substrate 12, the connection of the semiconductor device 1 and the mounting substrate 12 is strengthened, thereby enhancing impact resistance and connection strength. Preferably, the metal material is a thermal-conductive metal material. An effect of releasing heat generated in the semiconductor device can be achieved with the use of a high thermal-conductive material, which is effective especially for a low-heat-releasing semiconductor device that includes multiple layered semiconductor devices as shown in FIG. 9 or a semiconductor device including a heat releasing semiconductor, such as a logic circuit.

In a structure in which semiconductor devices 1C and 1D are layered as shown in FIG. 8, through holes 11D and 11E may be formed at the four corners of the upper semiconductor device 1C and the lower semiconductor device 1D, respectively.

The positions of the through holes 11D of the upper semiconductor device 1C are identical to those of the through holes 11E of the lower semiconductor device 1D. Thereby, a position setting of the upper and lower semiconductor devices 1C and 1D is enabled by the through holes 11D and 11E. Additionally, the upper and lower semiconductor devices 1C and 1D are reinforcingly connected to the mounting substrate 12 by the fixing member 14A being attached by insertion into the through holes 11D and 11E, enhancing the TC resistance, the impact resistance, and the connection strength of the semiconductor device, and the reliability of second mounting.

Also in this case, it is effective to change the type of the fixing member 14A according to each requirement for the TC resistance or the impact resistance.

As shown in FIG. 9, a brace member 23 may be formed at a given position on the mounting substrate 12. A position setting of the semiconductor device 1 to be mounted on the mounting substrate 12 is enabled by the brace member 23 being inserted into the through hole 11, enhancing mounting accuracy. Additionally, the through hole 11 into which the brace member 23 is inserted is filled with an adhesive 23a, thereby achieving reinforced connection.

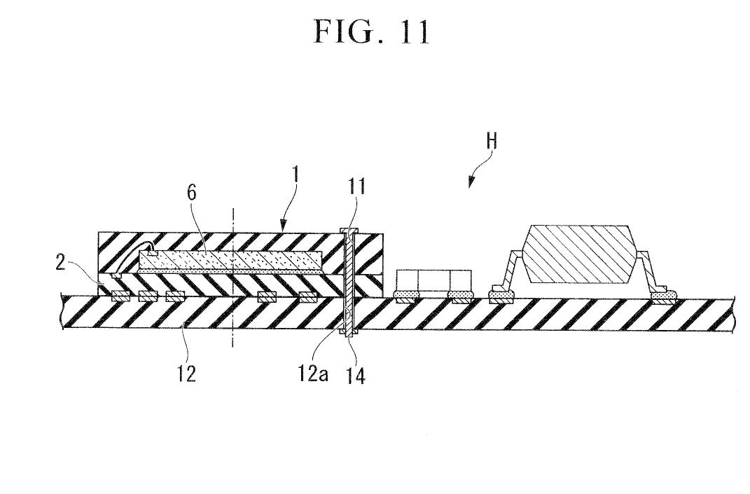

As shown in FIG. 10, the lands 4 of the semiconductor device 1 and the lands 13 of the mounting substrate 12 may be pressure-welded by a fixing member 14B, such as a screw, a bolt, or a nut, being inserted into the through bole 11 and fixed. Thereby, the mounting efficiency can be enhanced, and the external terminals 5 can be prevented from being broken due to stress. Additionally, the mounting height of the semiconductor device 1 can be lowered, implementing a more miniaturized and thinner electronic device H as shown in FIG. 11.

Further, the semiconductor device 1 can be easily repaired. Moreover, conductive materials, such as a plating or a bump, may be formed on the lands 4 and 13 to ensure the connection of the semiconductor device 1 and the mounting substrate 12.

If impact resistance is required, a hard metal member or the fixing member 14B is preferably used, and the fixing member 14 is preferably fixed to the semiconductor device 1 (through hole 11) and the mounting substrate 12 (through hole 12a) using an adhesive. As a result, the fixing member 14 is integrated with the semiconductor device 1 and the mounting substrate 12, and the connection of the semiconductor device 1 and the mounting substrate 12 is strengthened compared with when the adhesive is not used. Thereby, the impact resistance and the connection strength can be enhanced, and the reliability of the second mounting of the semiconductor device 1 can be enhanced.

As explained above, according to the electronic device H of the first embodiment, the fixing member 14 is provided for fixing the semiconductor device 1 onto the mounting substrate 12. As a result, the electronic parts included in the electronic device H can be reinforcingly connected to the mounting substrate 12. Therefore, the reliability of second mounting of the semiconductor device 1 can be enhanced.

Additionally, the type of the fixing member 14 can be selectively changed with respect to an electronic part of low reliability of second mounting. Thereby, various effects for enhancing the reliability can be achieved. As a result, the reliability of the electronic device can be enhanced.

The present invention is applicable to a semiconductor device in which a semiconductor chip is mounted on a package substrate, and an electronic device including the semiconductor device.

It is apparent that the present invention is not limited to the above embodiments, but may be modified and changed without departing from the scope and spirit of the invention.

What is claimed is:

1. A semiconductor device, comprising:
a wiring substrate that includes a plurality of connection pads provided on a top surface thereof and a plurality of lands provided on a bottom surface thereof and electrically connected to the connection pads, respectively;
a semiconductor chip mounted on the top surface of the wiring substrate;
a plurality of electrode pads provided on the semiconductor chip;
wirings that electrically connect the electrode pads and the connection pads, respectively;
a seal that is made of an insulating resin and covers at least the semiconductor chip and the wirings; and
a through hole that is provided on a peripheral region of the wiring substrate, into which a fixing member is to be attached by insertion.

2. The semiconductor device according to claim 1, wherein
the wiring substrate has substantially a quadrangular shape when planarly viewed, and
the semiconductor device comprises at least two through holes arranged at two opposing corners of the wiring substrate.

3. The semiconductor device according to claim 2, wherein the through holes are arranged at every corner of the wiring substrate.

4. The semiconductor device according to claim 2, wherein the through holes are arranged at intersections of the outermost arrangement lines along which the lands are arranged.

5. The semiconductor device according to claim 2, wherein the through holes are arranged outside intersections of the outermost arrangement lines along which the lands are arranged.

6. The semiconductor device according to claim 2, wherein at least one of the through holes has a shape different from the other through holes.

7. An electronic device, comprising:
the semiconductor device according to claim 1; and
a mounting substrate on which a plurality of electronic parts including the semiconductor device are mounted, wherein
the fixing member fixes the semiconductor device onto the mounting substrate.

8. The semiconductor device according to claim 7, wherein the fixing member is made of an elastic material.

9. The semiconductor device according to claim 7, wherein the fixing member is made of a metal material.

10. The semiconductor device according to claim 9, wherein the metal material is a thermal-conductive metal material.

11. The semiconductor device according to claim 7, wherein a brace member into which the fixing member is attached by insertion is provided on the mounting substrate at a position corresponding to the through hole.

12. The semiconductor device according to claim 7, wherein the fixing member pressure-wields the semiconductor device on the mounting substrate through the through hole.

13. The semiconductor device according to claim 7, wherein the semiconductor device is fixed to the mounting substrate through the fixing member onto which an adhesive is applied.
